(19) United States
(12) Patent Application Publication
(10) Pub. No.: US 2026/0186057 A1
(43) Pub. Date: Jul. 2, 2026

(54) AUTOMATIC CENTERING SYSTEM FOR MOTOR TESTING PLATFORM

(71) Applicants: CHROMA ATE INC., Taoyuan City (TW); Ming Chi University of Technology, New Taipei City (TW)

(72) Inventors: Ming-Yen Chen, New Taipei City (TW); Chih-Heng Chiu, New Taipei City (TW); Chun-Pin Yang, Taoyuan City (TW)

(21) Appl. No.: 19/191,106

(22) Filed: Apr. 28, 2025

(30) Foreign Application Priority Data
Dec. 31, 2024 (TW) 113151804

(51) Int. Cl. G01R 31/34; G01B 11/27

(52) U.S. Cl. CPC G01R 31/343; G01B 11/27

(57) ABSTRACT

An automatic centering system for a motor testing platform includes a host, a movable base, a first laser sensor assembly and a second laser sensor assembly. The movable base includes a clamping device and a multi-axial movable seat. The clamping device is arranged on the multi-axial movable seat and is configured to detachably clamp the motor to be tested. The laser sensor assemblies are arranged on a reference surface of a front stand of the motor testing platform to provide position detection in a horizontal plane or a vertical plane for an axis located at a detection position, so as to obtain first offset information and second offset information of the axis for the host to control the multi-axial movable seat and locate the axis at a centered position. Thus, automatic centering can be achieved and be further applied to production lines.

### BACKGROUND OF THE INVENTION

### Field of the Invention

The present disclosure relates to the technical field of a motor testing platform, and more particularly to an automatic centering system for a motor testing platform.

### Description of the Prior Art

In motor power testing, a motor to be tested needs to be locked on a front stand, and the axis of the motor to be tested is connected via an opening of the front stand to a coupling axis of a motor testing platform, further allowing the motor testing platform to perform a testing procedure.

Under a testing condition of a high rotational speed, the centered connection between the axis of the motor to be tested and the coupling axis becomes extremely critical. Even if a coupling can increase a connection tolerance between the axis and the coupling axis, due to the testing condition of the high rotational speed, the requirement for precision of the centered connection between the axis and the coupling axis becomes increasingly stringent. The more precise the centering, the more effectively vibration and noise can be reduced, which not only affects the service life of the motor testing platform but also risks damaging the axis of the motor to be tested, which serves as a transmission shaft

Conventionally, to achieve high-precision centering, installation personnel must accurately secure the motor to be tested on the front stand to achieve precise centering between the axis and the coupling axis. However, such operation consumes a significant amount of installation time.

### SUMMARY OF THE INVENTION

In some embodiments of the present disclosure, the issue of being time-consuming caused by centering operations performed by operating staff is addressed.

In some embodiments of the disclosure, a configuration for components of an automatic centering system is provided to enable the automatic centering system to provide accurate and efficient centering operations.

According to some embodiments, an automatic centering system for a motor testing platform provided is configured to adjust orientation of a motor to be tested to locate an axis of the motor to be tested at a centered position, for the motor testing platform to perform a testing procedure after a coupling axis extending along a first axis is coupled with the axis. The automatic centering system includes a host, a movable base, a first laser sensor assembly and a second laser sensor assembly. The movable base includes a clamping device and a multi-axial movable seat. The clamping device is arranged on the multi-axial movable seat and is configured to detachably clamp the motor to be tested. The first laser sensor assembly is arranged on a reference surface of a front stand of the motor testing platform to provide position detection in a horizontal plane for the axis located at a detection position, so as to obtain first offset information of the axis in the horizontal plane of a horizontal axis perpendicular to the first axis. The second laser sensor assembly is arranged on the reference surface to provide position detection in a vertical plane for the axis, so as to obtain second offset information of the axis in the vertical plane of a vertical axis perpendicular to the horizontal axis. The host is configured to control the multi-axial movable seat according to the first offset information and the second offset information to locate the axis at the centered position.

According to some embodiments, a first sensing region of the first laser sensor assembly may be defined on the horizontal plane. When the axis is at the detection position, a side edge of the axis is defined with a first front identification point, a second front identification point, a first back identification point and a second back identification point located within the first sensing region on the horizontal plane. A connecting line between the first front identification point and the second front identification point is parallel to the horizontal axis. A connecting line between the first back identification point and the second back identification point is parallel to the horizontal axis. A connecting line between the first front identification point and the first back identification point is parallel to the first axis. A second sensing region of the second laser sensor assembly may be defined on the vertical plane. When the axis is at the detection position, the side edge of the axis is defined with a third front identification point, a fourth front identification point, a third back identification point and a fourth back identification point located within the second sensing region on the vertical plane. A connecting line between the third front identification point and the fourth front identification point is parallel to the vertical axis. A connecting line between the third back identification point and the fourth back identification point is parallel to the vertical axis. A connecting line between the third front identification point and the third back identification point is parallel to the first axis.

According to some embodiments, the first offset information may include first and second horizontal offsets. The first horizontal offset refers to a difference between a distance between the first front identification point and a first front reference point within the first sensing region and a distance between the second front identification point and a second front reference point within the first sensing region. The second horizontal offset refers to a difference between a distance between the first back identification point and a first back reference point within the first sensing region and a distance between the second back identification point and a second back reference point within the first sensing region. When the axis is located at the centered position, both of the first and second horizontal offsets may be less than or equal to a threshold.

According to some embodiments, the second offset information may include first and second vertical offsets. The first vertical offset refers to a difference between a distance between the third front identification point and a third front reference point within the second sensing region and a distance between the fourth front identification point and a fourth front reference point within the second sensing region. The second vertical offset refers to a difference between a distance between the third back identification point and a third back reference point within the second sensing region and a distance between the fourth back identification point and a fourth back reference point within the second sensing region. When the axis is located at the centered position, both of the first and second vertical offsets may be less than or equal to the threshold.

According to some embodiments, all of the first front reference point, the first back reference point, the second front reference point and the second back reference point may be located on an edge of the first sensing region. All of the third front reference point, the third back reference point, the fourth front reference point and the fourth back reference point may be located on an edge of the second sensing region.

According to some embodiments, the first laser sensor assembly may include first and second horizontal reference objects protruding from the reference surface and at least partially located within the first sensing region, for associated reference points to be individually defined on a straight edge of the first or second horizontal reference object within the first sensing region. The second laser sensor assembly may include first and second vertical reference objects protruding from the reference surface and at least partially located within the second sensing region, for associated reference points to be individually defined on a straight edge of the first or second vertical reference object within the second sensing region.

According to some embodiments, the multi-axial movable seat may include a first axial moving device, a horizontal axial moving device, a vertical axial moving device, a first rotating device and a second rotating device. The first rotating device regards the vertical axis as a rotating axis, and the second rotating device regards the horizontal axis as a rotating axis. The host is operable to obtain a vertical-axis angle deviation based on the distance between the first front identification point and the first front reference point and based on the distance between the first back identification point and the first back reference point, so as to correspondingly control the first rotating device. The host is operable to obtain a horizontal-axis angle deviation based on the distance between the third front identification point and the third front reference point and based on the distance between the third back identification point and the third back reference point, so as to correspondingly control the second rotating device.

According to some embodiments, when performing the automatic centering operation, the host is configured to perform, sequentially or according to a condition, operations of: an initialization step, an offset information acquisition step, an angle determination step, an offset determination step, an angle adjustment step, an offset adjustment step and a centering completion step.

Accordingly, with the arranged positions of the first laser sensor assembly and the second laser sensor assembly, in conjunction with the front stand of an existing motor testing platform, the status of the axis of the motor to be tested can be effectively detected. Under the control of the movable base, automatic centering operation can be achieved and further provided to production lines to achieve automatic centering. Meanwhile, the issue of vibration caused by the deviation or misalignment between two axes can also be mitigated, thereby further extending the service life of the motor testing platform.

### BRIEF DESCRIPTION OF THE DRAWINGS

FIG. 1 is a perspective diagram of a motor testing platform having an automatic centering system according to some embodiments;

FIG. 2 is a front schematic diagram of the front stand according to the embodiment in FIG. 1;

FIG. 3 is a schematic diagram of a detection viewing angle in a horizontal plane of an automatic centering system according to some embodiments;

FIG. 4 is a schematic diagram of a detection viewing angle in a vertical plane of an automatic centering system according to some embodiments;

FIG. 5 is a schematic diagram of a detection viewing angle in a horizontal plane of an automatic centering system according to another embodiment; and

FIG. 6 is a flowchart of a centering procedure performed by an automatic centering system according to some embodiments.

### DETAILED DESCRIPTION OF THE EMBODIMENTS

The objectives, features, and advantages of the present disclosure are hereunder illustrated with specific embodiments, depicted with drawings, and described below.

In the disclosure, descriptive terms such as “a” or “one” are used to describe the unit, component, structure, device, module, portion, section or region, and are for illustration purposes and providing generic meaning to the scope of the present invention. Therefore, unless otherwise explicitly specified, such description should be understood as including one or at least one, and a singular number also includes a plural number.

In the disclosure, descriptive terms such as “include, comprise, have” or other similar terms are not for merely limiting the essential elements listed in the disclosure, but can include other elements that are not explicitly listed and are however usually inherent in the units, components, structures, devices, modules, portions, sections or regions.

In the disclosure, the terms similar to ordinals such as “first” or “second” described are for distinguishing or referring to associated identical or similar components, structures, portions, or regions, and do not necessarily imply the orders of these components, structures, portions, sections or regions in a spatial aspect. It should be understood that, in some situations or configurations, the ordinal terms could be interchangeably used without affecting the implementation of the present invention.

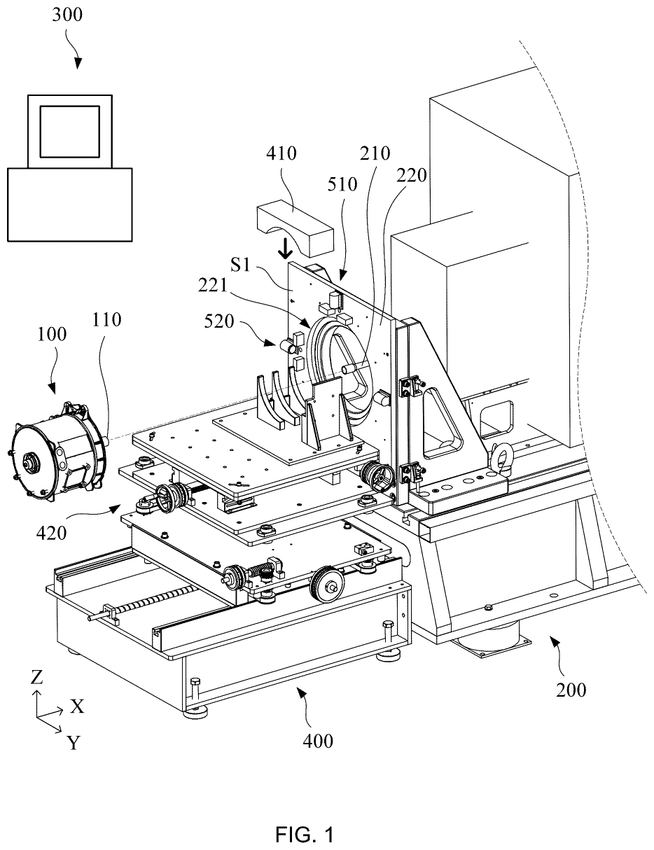

Refer to FIG. 1 showing a perspective diagram of a motor testing platform having an automatic centering system according to some embodiments. A motor testing platform 200 includes a coupling axis 210 extending along a first axis X and a front stand 220 arranged at a front end. The coupling axis 210 is configured to couple with an axis 110 of the motor to be tested 100, for example, by means of a coupling. The front stand 220 has an opening 221 and a reference surface S1. The opening 221 is usually configured such that a center line C of the coupling axis 210 passes through a center of the opening 221 and is aligned with a normal vector of the reference surface S1.

The automatic centering system of the motor testing platform 200 includes a host 300, a movable base 400, a first laser sensor assembly 510 and a second laser sensor assembly 520. The movable base 400 includes a clamping device 410 and a multi-axial movable seat 420. The clamping device 410 may be implemented by a quick-detachable device such as a fastener or an elastic clamp. The host 300 is operable to correspondingly control the motor testing platform 200, the movable base 400, the first laser sensor assembly 510 and the second laser sensor assembly 520 and/or receive corresponding data and information, and is usually connected by a wired and/or wireless means (not shown).

In some testing environments, the motor to be tested 100 is usually locked on the reference surface S1 to align the axis 110 of the motor to be tested 100 with the center line C and couple the axis 110 with the coupling axis 210, and the host 300 then controls the motor testing platform 200 to perform a testing procedure. In some embodiments of the present disclosure, the motor to be tested 100 is not locked on the reference surface S1 of the front stand 220, but is fixed on the movable base 400 by the clamping device 410. The host 300 correspondingly obtains first offset information and second offset information by the first laser sensor assembly 510 and the second laser sensor assembly 520, and controls the multi-axial movable seat 420 of the movable base 400 according to the obtained information, so as to reduce or eliminate the level of offset or deviation to achieve the automatic centering operation.

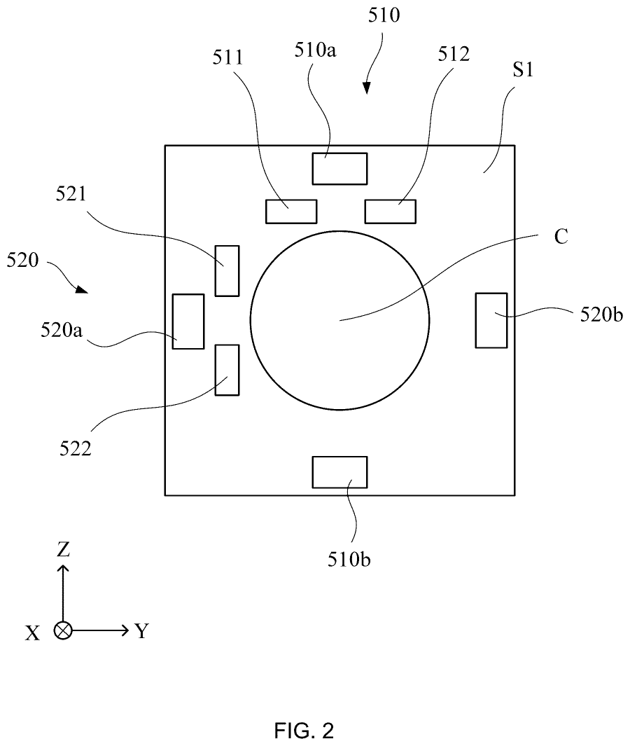

Refer to both FIG. 1 and FIG. 2, FIG. 2 shows a front schematic diagram of the front stand according to the embodiment in FIG. 1. The first laser sensor assembly 510 is arranged on the reference surface S1 of the front stand 220, and provides position detection in a horizontal plane for the axis 110 of the motor to be tested 100 clamped on the multi-axial movable seat 420 and located at a detection position. The laser sensor assembly (510, 520) has a laser emitting end (510a, 520a) and a laser receiving end (510b, 520b), wherein the emitting end and the receiving end may be swapped. On the basis of the collimation characteristics of laser, a part at which laser light is blocked is presented on a received image at the receiving end, such that a degree of offset or deviation can be accurately calculated based on this image. The detection position above refers to that the axis 110 of the motor to be tested 100 is located within detection ranges of the first laser sensor assembly 510 and the second laser sensor assembly 520.

As shown in FIG. 2, the first laser sensor assembly 510 may include a first horizontal reference object 511 and a second horizontal reference object 512 protruding from the reference surface S1. The second laser sensor assembly 520 may include a first vertical reference object 521 and a second vertical reference object 522 protruding from the reference surface S1. In some other embodiments, these protruding reference objects may be omitted; however, these protruding reference objects can further improve precision to enhance reliability.

Overall, the first laser sensor assembly 510 provides position detection in the horizontal plane for the axis 110, wherein this horizontal plane is defined along a horizontal axis Y that is perpendicular to the first axis X. Thus, such configuration above can be used to obtain the first offset information of the axis 110. The second laser sensor assembly 520 provides position detection in the vertical plane for the axis 110, wherein this vertical plane is defined along a vertical axis Z that is perpendicular to the first axis X. Thus, such configuration above can be used to obtain the second offset information of the axis 110.

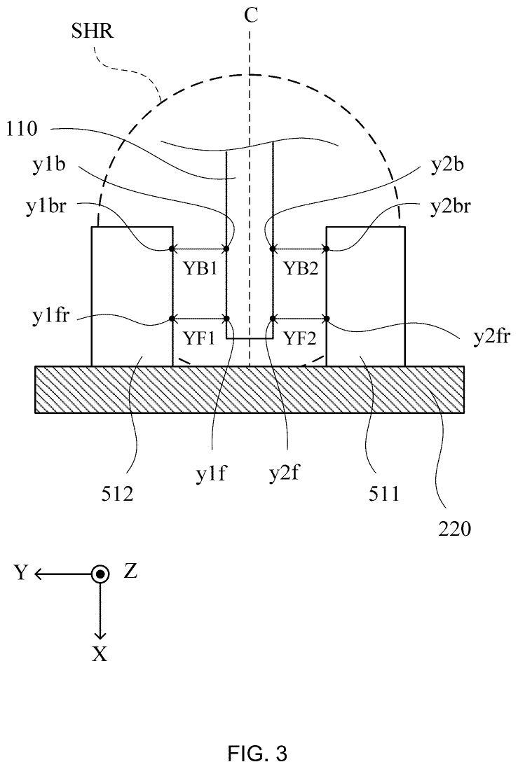

Refer to both FIG. 1 and FIG. 3, FIG. 3 shows a schematic diagram of a detection viewing angle in a horizontal plane of an automatic centering system according to some embodiments. A first sensing region SHR of the first laser sensor assembly 510 is defined on the horizontal plane above. When the axis 110 of the motor to be tested 100 is at the detection position, a side edge of the axis 110 may be defined with a first front identification point y1f, a second front identification point y2f, a first back identification point y1b and a second back identification point y2b located within the first sensing region SHR on the horizontal plane. In the received image presented at the receiving end, this detection range of the first sensing region SHR can be seen. Within this detection range, the first horizontal reference object 511 and the second horizontal reference object 512 shield the laser beam and resulting in shadows in the received image, and the axis 110 located within the detection range also shields the laser beam and presents a shadow in the received image. Thus, the state above can be used to obtain various information. The following spatial relationships can be observed from FIG. 3: a connecting line between the first front identification point y1f and the second front identification point y2f is parallel to the horizontal axis Y; a connecting line between the first back identification point y1b and the second back identification point y2b is parallel to the horizontal axis Y; and a connecting line between the first front identification point y1f and the first back identification point y1b is parallel to the first axis X.

The first offset information includes a first horizontal offset and a second horizontal offset. The first horizontal offset refers to a difference between a distance YF1 between the first front identification point y1f and a first front reference point y1fr and a distance YF2 between the second front identification point y2f and a second front reference point y2fr. When the difference between the two distances YF1 and YF2 is zero or less than a set threshold, it means that the degree of offset of the axis 110 in terms of the first horizontal offset meets a requirement and does not need to be adjusted, otherwise adjustment needs to be made so that the difference between the two distances YF1 and YF2 is zero or less than a set threshold.

The second horizontal offset refers to a difference between a distance YB1 between the first back identification point y1b and a first back reference point y1br and a distance YB2 between the second back identification point y2b and a second back reference point y2br. When the difference between the two distances YB1 and YB2 is zero or less than a set threshold, it means that the degree of offset of the axis 110 in terms of the second horizontal offset meets a requirement and does not need to be adjusted, otherwise adjustment needs to be made so that the difference between the two distances YB1 and YB2 is zero or less than a set threshold.

When the first horizontal offset and the second horizontal offset are not both zero or both less than a set threshold, the host 300 can determine that there is an inclined angle of the axis 110 in a plane of the horizontal axis Y (the horizontal plane), so as to eliminate such inclined angle by rotation performed in the vertical axis Z.

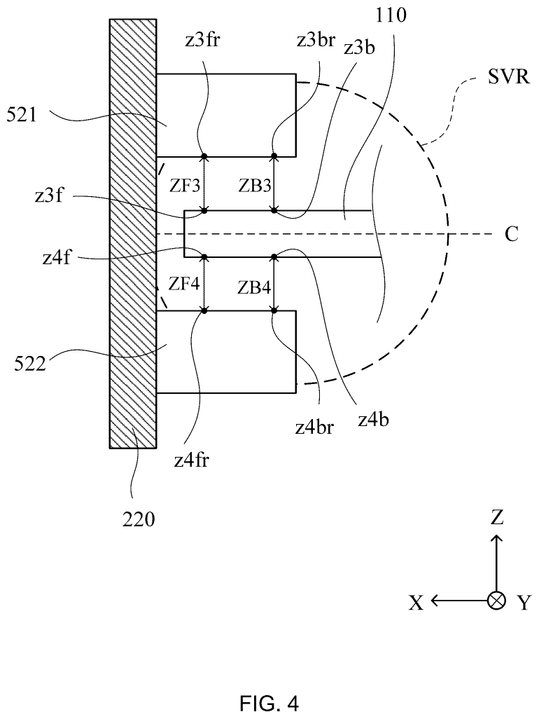

Refer to both FIG. 1 and FIG. 4, FIG. 4 shows a schematic diagram of a detection viewing angle in a vertical plane of an automatic centering system according to some embodiments. A second sensing region SVR of the second laser sensor assembly 520 is defined on the vertical plane above. When the axis 110 of the motor to be tested 100 is at the detection position, a side edge of the axis 110 may be defined with a third front identification point z3f, a fourth front identification point z4f, a third back identification point z3b and a fourth back identification point z4b located within the second sensing region SVR on the vertical plane. In the received image presented at the receiving end, this detection range of the second sensing region SVR can be seen. Within this detection range, the first vertical reference object 521 and the second vertical reference object 522 shield the laser beam, resulting in shadows in the received image, and the axis 110 located within the detection range also shields the laser beam and results in a shadow in the received image. Thus, the state above can be used to obtain various information. A spatial state below can be observed from FIG. 4; that is, a connecting line between the third front identification point z3f and the fourth front identification point z4f is parallel to the vertical axis Z, a connecting line between the third back identification point z3b and the fourth back identification point z4b is parallel to the vertical axis Z, and a connecting line between the third front identification point z3f and the third back identification point z3b is parallel to the first axis X.

The second offset information includes a first vertical offset and a second vertical offset. The first vertical offset refers to a difference between a distance ZF3 between the third front identification point z3f and a third front reference point z3fr and a distance ZF4 between the fourth front identification point z4f and a fourth front reference point z4fr. When the difference between the two distances ZF3 and ZF4 is zero or less than a set threshold, it indicates that the degree of offset of the axis 110 in terms of the first vertical offset meets a requirement and no adjustment is necessary, otherwise adjustment needs to be made so that the difference between the two distances ZF3 and ZF4 is zero or less than a set threshold.

The second vertical offset refers to a difference between a distance ZB3 between the third back identification point z3b and a third back reference point z3br and a distance ZB4 between the fourth back identification point z4b and a fourth back reference point z4br. When the difference between the two distances ZB3 and ZB4 is zero or less than a set threshold, it indicates that the degree of offset of the axis 110 in terms of the second vertical offset meets a requirement and does not need to be adjusted, otherwise adjustment needs to be made so that the difference between the two distances ZB3 and ZB4 is zero or less than a set threshold.

When the first vertical offset and the second vertical offset are not both zero or both less than a set threshold, the host 300 can determine that there is an inclined angle of the axis 110 on a plane of the vertical axis Z (the vertical plane), so as to eliminate such inclined angle by rotation performed in the horizontal axis Y.

The inclined angle in the plane of the horizontal axis Y (the horizontal plane) or the plane of the vertical axis Z (the vertical plane) can be derived from the distance information above, and thus algorithms performed based on, for example, trigonometric functions or other means, are omitted herein.

As shown in FIG. 3, each of the reference points y1fr, y1br, y2fr and y2br is defined on a straight edge of the corresponding first horizontal reference object 511 or second horizontal reference object 512 within the first sensing region SHR. As shown in FIG. 4, each of the reference points z3fr, z3br, z4fr and z4br is defined on a straight edge of the corresponding first vertical reference object 521 or second vertical reference object 522 within the second sensing region SVR.

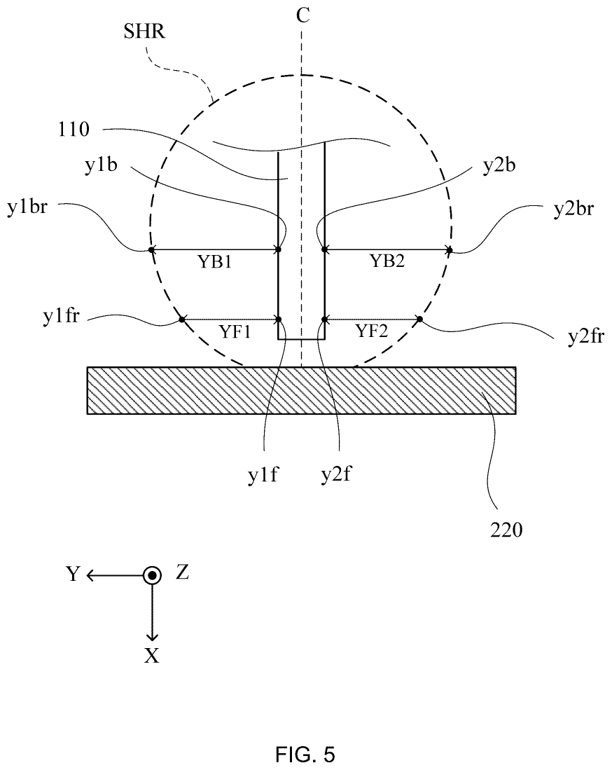

Refer to FIG. 5 showing a schematic diagram of a detection viewing angle in a horizontal plane of an automatic centering system according to another embodiment. In this embodiment, the protruding reference objects are not used, and edges (for example, physical borders or imaginary borders) of sensing regions of laser sensor assemblies are directly used instead. Taking FIG. 5 for example, each of the reference points y1fr, y1br, y2fr and y2br is defined on an edge (a physical border) of a sensing region of the first sensing region SHR, and similarly (not shown), each of the reference points z3fr, z3br, z4fr and z4br may also be defined on an edge of a sensing region of the second sensing region SVR. In some other embodiments, imaginary borders may also be defined within a sensing region for the host 300 to perform corresponding operations.

The multi-axial movable seat is configured to provide the motor to be tested 100 with capability of adjustment in multiple directions. For example, the multi-axial movable seat may include a first axial moving device (moving in an axial direction of the first axis X), a horizontal axial moving device (moving in an axial direction of the horizontal axis Y), a vertical axial moving device (moving in an axial direction of the vertical axis Z), a first rotating device (rotating about the vertical axis Z as a rotating axis) and a second rotating device (rotating about the horizontal axis Y as a rotating axis).

When the first horizontal offset and the second horizontal offset are not both zero or both less than a set threshold, the host 300 may obtain a vertical-axis angle deviation (for example, an inclined angle) based on the distance YF1 between the first front identification point y1f and the first front reference point y1fr and based on the distance YB1 between the first back identification point y1b and the first back reference point y1br, so as to correspondingly control the first rotating device to rotate about the vertical axis Z so as to eliminate this inclined angle. Similarly, when the first vertical offset and the second vertical offset are not both zero or both less than a set threshold, the host 300 may obtain a horizontal-axis angle deviation (for example, an inclined angle) based on the distance ZF3 between the third front identification point z3f and the third front reference point z3fr and based on the distance ZB3 between the third back identification point z3b and the third back reference point z3br, so as to correspondingly control the second rotating device to rotate about the horizontal axis Y so as to eliminate this inclined angle.

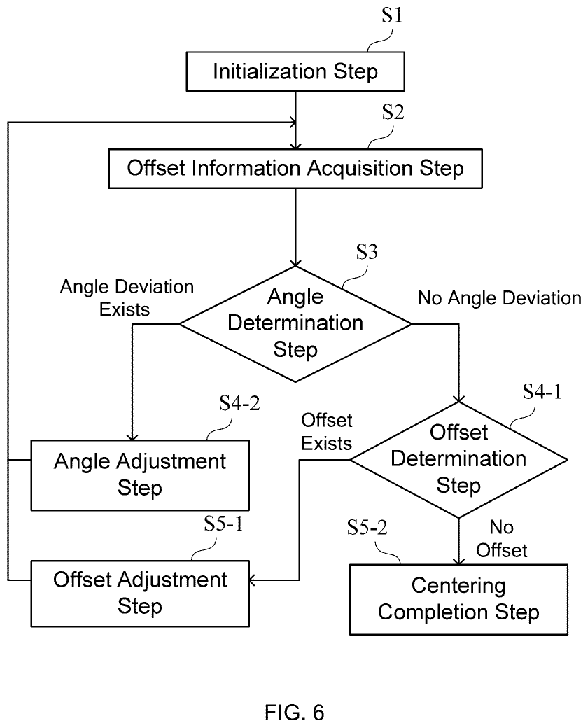

Refer to both FIG. 1 and FIG. 6, FIG. 6 shows a flowchart of a centering procedure performed by an automatic centering system according to some embodiments. When performing the automatic centering procedure, in order to achieve a correct and efficient control operation, the host may perform the following operations in sequence.

In initialization step S1, the host 300 controls the first axial moving device to locate the axis 110 of the motor to be tested 100 at the detection position.

In offset information acquisition step S2, the host 300 obtains the first offset information of the axis 110 and the vertical-axis angle deviation by the first laser sensor assembly 510, and obtains the second offset information of the axis 110 and the horizontal-axis angle deviation by the second laser sensor assembly 520.

In angle determination step S3, when both of the vertical-axis angle deviation and the horizontal-axis angle deviation are less than or equal to a predetermined angle, the host 300 proceeds to offset determination step S4-1; otherwise, it proceeds to angle adjustment step S4-2.

In offset determination step S4-1, the host 300 performs offset determination. When both of the first offset information and the second offset information are less than or equal to the threshold, the host 300 proceeds to centering completion step S5-2; otherwise, it proceeds to offset adjustment step S5-1.

In angle adjustment step S4-2, the host 300 correspondingly controls the first rotating device based on the vertical-axis angle deviation, and correspondingly controls the second rotating device based on the horizontal-axis angle deviation to reduce the deviation, and returns to offset information acquisition step S2.

In offset adjustment step S5-1, the host 300 correspondingly controls the horizontal axial moving device based on the first offset information, and correspondingly controls the vertical axial moving device based on the second offset information to reduce the offset, and returns to offset information acquisition step S2.

In centering completion step S5-2, the host 300 controls the first axial moving device to move the motor to be tested 100 toward the motor testing platform 200, thereby completing coupling of the axis 110 with the coupling axis 210.

The motor testing platform 200 then subsequently performs various testing procedures for the motor.

In conclusion, based on the first and second laser sensor assemblies, along with the definitions of the reference points and identification points, the automatic centering operation can be accurately and efficiently completed and thus be suitable for production lines. Moreover, by significantly reducing the amplitude of deviation between two axes, the service life of the motor testing platform is further extended.

The present invention has been disclosed through various embodiments. However, it should be understood by those skilled in the art that the embodiments are merely illustrative and not restrictive of the scope of the present invention. After perusing this specification, persons skilled in the art may come up with other aspects and embodiments without departing from the scope of the present disclosure. All equivalent variations and replacements of the aspects and the embodiments must fall within the scope of the present disclosure. Therefore, the scope of the protection of rights of the present invention shall be defined by the appended claims.

What is claimed is:

1. An automatic centering system for a motor testing platform, configured to adjust orientation of a motor to be tested to locate an axis of the motor to be tested at a centered position, for the motor testing platform to perform a testing procedure after a coupling axis extending along a first axis is coupled with the axis; the automatic centering system, comprising:
a host;
a movable base, comprising a clamping device and a multi-axial movable seat, the clamping device arranged on the multi-axial movable seat and configured to detachably clamp the motor to be tested;
a first laser sensor assembly, arranged on a reference surface of a front stand of the motor testing platform to provide position detection in a horizontal plane for the axis located at a detection position, so as to obtain first offset information of the axis in the horizontal plane of a horizontal axis perpendicular to the first axis; and
a second laser sensor assembly, arranged on the reference surface to provide position detection in a vertical plane for the axis, so as to obtain second offset information of the axis in the vertical plane of a vertical axis perpendicular to the horizontal axis,
wherein the host is configured to control the multi-axial movable seat according to the first offset information and the second offset information to locate the axis at the centered position.

2. The automatic centering system according to claim 1, wherein a first sensing region of the first laser sensor assembly is defined on the horizontal plane; at the detection position, a side edge of the axis is defined with a first front identification point, a second front identification point, a first back identification point and a second back identification point located within the first sensing region on the horizontal plane; a connecting line between the first front identification point and the second front identification point is parallel to the horizontal axis, a connecting line between the first back identification point and the second back identification point is parallel to the horizontal axis, and a connecting line between the first front identification point and the first back identification point is parallel to the first axis; wherein a second sensing region of the second laser sensor assembly is defined on the vertical plane; at the detection position, the side edge of the axis is defined with a third front identification point, a fourth front identification point, a third back identification point and a fourth back identification point within the second sensing region on the vertical plane; a connecting line between the third front identification point and the fourth front identification point is parallel to the vertical axis, a connecting line between the third back identification point and the fourth back identification point is parallel to the vertical axis, and a connecting line between the third front identification point and the third back identification point is parallel to the first axis.

3. The automatic centering system according to claim 2, wherein the first offset information comprises a first horizontal offset and a second horizontal offset, the first horizontal offset refers to a difference between a distance between the first front identification point and a first front reference point within the first sensing region and a distance between the second front identification point and a second front reference point within the first sensing region, the second horizontal offset refers to a difference between a distance between the first back identification point and a first back reference point within the first sensing region and a distance between the second back identification point and a second back reference point within the first sensing region, and wherein when the axis is located at the centered position, both of the first and second horizontal offsets are less than or equal to a threshold.

4. The automatic centering system according to claim 3, wherein the second offset information comprises a first vertical offset and a second vertical offset, the first vertical offset refers to a difference between a distance between the third front identification point and a third front reference point within the second sensing region and a distance between the fourth front identification point and a fourth front reference point within the second sensing region, the second vertical offset refers to a difference between a distance between the third back identification point and a third back reference point within the second sensing region and a distance between the fourth back identification point and a fourth back reference point within the second sensing region, and wherein when the axis is located at the centered position, both of the first and second vertical offsets are less than or equal to the threshold.

5. The automatic centering system according to claim 4, wherein all of the first front reference point, the first back reference point, the second front reference point and the second back reference point are located on an edge of the first sensing region, and all of the third front reference point, the third back reference point, the fourth front reference point and the fourth back reference point are located on an edge of the second sensing region.

6. The automatic centering system according to claim 4, wherein the first laser sensor assembly comprises a first horizontal reference object and a second horizontal reference object protruding from the reference surface and at least partially located within the first sensing region, the first front reference point and the first back reference point are defined on a straight edge of the first horizontal reference object within the first sensing region, and the second front reference point and the second back reference point are defined on a straight edge of the second horizontal reference object within the first sensing region; wherein the second laser sensor assembly comprises a first vertical reference object and a second vertical reference object protruding from the reference surface and at least partially located within the second sensing region, the third front reference point and the third back reference point are defined on a straight edge of the first vertical reference object within the second sensing region, and the fourth front reference point and the fourth back reference point are defined on a straight edge of the second vertical reference object within the second sensing region.

7. The automatic centering system according to claim 5, wherein the multi-axial movable seat comprises a first axial moving device, a horizontal axial moving device, a vertical axial moving device, a first rotating device and a second rotating device, the first rotating device regards the vertical axis as a rotating axis, and the second rotating device regards the horizontal axis as a rotating device, wherein the host obtains a vertical-axis angle deviation based on a distance between the first front identification point and the first front reference point and based on a distance between the first back identification point and the first back reference point so as to correspondingly control the first rotating device, and the host obtains a horizontal-axis angle deviation based on a distance between the third front identification point and the third front reference point and based on a distance between the third back identification point and the third back reference point so as to correspondingly control the second rotating device.

8. The automatic centering system according to claim 7, wherein the host is configured, while performing an automatic centering procedure, to perform operations of:
an initialization step to control the first axial moving device to locate the axis of the motor to be tested at the detection position;
an offset information acquisition step to obtain the first offset information of the axis and the vertical-axis angle deviation by the first laser sensor assembly, and obtain the second offset information of the axis and the horizontal-axis angle deviation by the second laser sensor assembly;
an angle determination step to enter an offset determination step when both of the vertical-axis angle deviation and the horizontal-axis angle deviation are less than or equal to a predetermined angle, otherwise enter an angle adjustment step;
the offset determination step to enter a centering completion step when both of the first offset information and the second offset information are less than or equal to the threshold, otherwise enter an offset adjustment step;
the angle adjustment step to correspondingly control the first rotating device according to the vertical-axis angle deviation, and correspondingly control the second rotating device according to the horizontal-axis angle deviation to reduce a deviation, and return to the offset information acquisition step;
the offset adjustment step to correspondingly control the horizontal axial moving device according to the first offset information, and correspondingly control the vertical axial moving device according to the second offset information to reduce an offset, and return to the offset information acquisition step; and
the centering completion step to control the first axial moving device to move the motor to be tested toward the motor testing platform and couple the axis with and the coupling axis.

9. The automatic centering system according to claim 6, wherein the multi-axial movable seat comprises a first axial moving device, a horizontal axial moving device, a vertical axial moving device, a first rotating device and a second rotating device, the first rotating device regards the vertical axis as a rotating axis, and the second rotating device regards the horizontal axis as a rotating device, wherein the host obtains a vertical-axis angle deviation based on a distance between the first front identification point and the first front reference point and based on a distance between the first back identification point and the first back reference point so as to correspondingly control the first rotating device, and the host obtains a horizontal-axis angle deviation based on a distance between the third front identification point and the third front reference point and based on a distance between the third back identification point and the third back reference point so as to correspondingly control the second rotating device.

10. The automatic centering system according to claim 9, wherein the host is configured, while performing an automatic centering procedure, to perform operations of:
an initialization step to control the first axial moving device to locate the axis of the motor to be tested at the detection position;
an offset information acquisition step to obtain the first offset information of the axis and the vertical-axis angle deviation by the first laser sensor assembly, and obtain the second offset information of the axis and the horizontal-axis angle deviation by the second laser sensor assembly;
an angle determination step to enter an offset determination step when both of the vertical-axis angle deviation and the horizontal-axis angle deviation are less than or equal to a predetermined angle, otherwise enter an angle adjustment step;
the offset determination step to enter a centering completion step when both of the first offset information and the second offset information are less than or equal to the threshold, otherwise enter an offset adjustment step;
the angle adjustment step to correspondingly control the first rotating device according to the vertical-axis angle deviation, and correspondingly control the second rotating device according to the horizontal-axis angle deviation to reduce a deviation, and return to the offset information acquisition step;
the offset adjustment step to correspondingly control the horizontal axial moving device according to the first offset information, and correspondingly control the vertical axial moving device according to the second offset information to reduce an offset, and return to the offset information acquisition step; and
the centering completion step to control the first axial moving device to move the motor to be tested toward the motor testing platform and couple the axis with and the coupling axis.
